(19) United States
(12) Patent Application Publication
(10) Pub. No.: US 2019/0152186 A1
(43) Pub. Date: May 23, 2019

(54) STRUCTURE, ELECTRONIC APPARATUS, DECORATIVE FILM, AND STRUCTURE PRODUCTION METHOD

(71) Applicant: SONY CORPORATION, TOKYO (JP)

(72) Inventors: KAZUHITO SHIMODA, KANAGAWA (JP); ATSUHIRO ABE, KANAGAWA (JP)

(21) Appl. No.: 16/091,239

(22) PCT Filed: Apr. 5, 2017
(86) PCT No.: PCT/JP2017/014167

§ 371 Date: Oct. 4, 2018

(30) Foreign Application Priority Data
Apr. 12, 2016 (JP) 2016-079263

(51) Int. Cl. B32B 3/10; B32B 15/08; B29C 45/16; C23C 14/20; C23C 14/58; B32B 15/20; H05K 5/04; H05K 5/02

(52) U.S. Cl. CPC B32B 3/10; B32B 15/08; B29C 45/1679; C23C 14/20; B29L 2031/3481; B32B 15/20; H05K 5/04; H05K 5/0243; C23C 14/5886

(57) ABSTRACT

A structure according to an embodiment of the present technology includes a decorative film and a casing portion. The decorative film includes a metal layer that includes a first area in which an addition concentration of a predetermined element is relatively high, a second area in which the addition concentration is relatively lower than that of the first area, and minute cracks that are formed using the first area as a reference. The casing portion includes a to-be-decorated area to which the decorative film is to be bonded.

### TECHNICAL FIELD

The present technology relates to a structure applicable to an electronic apparatus and the like, an electronic apparatus to which the structure is applied, a decorative film, and a casing component production method.

### BACKGROUND ART

From the past, as a casing component of an electronic apparatus and the like, a member capable of transmitting electromagnetic waves of a millimeter wave or the like while having a metallic appearance has been devised. For example, Patent Literature 1 discloses an exterior component for mounting an automobile radar on an automobile emblem. For example, indium is vapor-deposited on a resin film, and this film is attached to a surface layer of the emblem by an insert molding method. Accordingly, it becomes possible to produce an exterior component that has a decorative metallic luster and does not have an absorption range in an electromagnetic wave frequency band due to an island-like structure of indium (paragraph [0006] in specification of Patent Literature 1).

However, in the method of forming the island-like structure of indium, there is a problem that it is difficult to form a uniform film thickness as a whole in a case where a vapor deposition area is large or the like. Further, there is also a problem that the island-like structure is easily broken due to a temperature of the resin to be poured in when forming the casing component (paragraphs [0007] and [0008] in specification of Patent Literature 1, etc.).

In order to solve this problem, the following technology is disclosed in Patent Literature 1. Specifically, a sea-island structure in which metal areas are islands and a non-metal area surrounding the islands is a sea is artificially formed with regularity. Then, each of the metal areas is insulated from one another by the non-metal area, and an area of the metal areas and an interval between adjacent metal areas are controlled appropriately. Accordingly, an electromagnetic-wave transmissive material comparable to a film on which indium is vapor-deposited can be obtained (paragraph [0013] in specification of Patent Literature 1, etc.).

### CITATION LIST

### Patent Literature

Patent Literature 1: Japanese Patent Application Laid-open No. 2010-251899

### DISCLOSURE OF INVENTION

### Technical Problem

As described above, there is a demand for a technology for producing a member that is capable of transmitting radio waves while having a metallic luster and also has a high design property.

In view of the circumstances as described above, an object of the present technology is to provide a structure that is capable of transmitting radio waves while having a metallic appearance and also has a high design property, an electronic apparatus to which the structure is applied, a decorative film, and a structure production method.

### Solution to Problem

To attain the object described above, a structure according to an embodiment of the present technology includes a decorative film and a casing portion.

The decorative film includes a metal layer that includes a first area in which an addition concentration of a predetermined element is relatively high, a second area in which the addition concentration is relatively lower than that of the first area, and minute cracks that are formed using the first area as a reference.

The casing portion includes a to-be-decorated area to which the decorative film is to be bonded.

In this structure, the predetermined element is added to the metal layer, and the minute cracks are formed using the first area in which the addition concentration is relatively high as a reference. Accordingly, it becomes possible to form the metal layer by aluminum or the like having a high reflectance, for example. As a result, it becomes possible to realize a structure that is capable of transmitting radio waves while having a metallic appearance and also has a high design property.

The predetermined element may be oxygen or nitrogen.

By adding oxygen or nitrogen, it becomes possible to form minute cracks while maintaining a high reflectance and thus realize a structure having a high design property.

The metal layer may be formed of aluminum or silver.

Since the metal layer capable of transmitting radio waves can be realized using aluminum or silver having a high reflectance, a high design property can be exhibited.

The metal layer may have a thickness of 50 nm or more and 300 nm or less.

Accordingly, it becomes possible to exhibit sufficient radio wave transmittivity while maintaining a high reflectance.

A pitch of the minute cracks may be within a range of 1 μm or more and 500 μm or less.

Accordingly, it becomes possible to exhibit sufficient radio wave transmittivity.

A surface reflectance of a visible light area of the metal layer may be 70% or more.

Accordingly, it becomes possible to exhibit an extremely-high design property due to a metallic luster.

The decorative film may include a protection layer laminated on the metal layer, and a surface reflectance of a visible light area of the protection layer may be 65% or more.

Even in a case where the protection layer is formed, an extremely-high design property can be exhibited.

The minute cracks may be formed to have a net-like appearance.

By biaxial stretching, for example, it becomes possible to easily form minute net-like cracks while using the first area as a reference. For example, it is possible to form minute cracks by a low stretching rate. As a result, it becomes possible to suppress a deformation of the decorative film due to stretching, or the like, and thus sufficiently suppress an occurrence of defects at a time of producing the structure.

The decorative film may include a base portion that supports the metal layer, a tensile breakage intensity of the base portion being smaller than that of the metal layer.

By using the base portion having a smaller tensile breakage intensity than the metal layer, minute cracks can be formed by a low stretching rate.

The base portion may be a base film.

The metal layer may be formed on a base film having a small tensile breakage intensity.

The base portion may be a coating layer formed on a base film.

Accordingly, it becomes possible to form cracks by a low stretching rate while using a base film having a large tensile breakage intensity.

The addition concentration may become lower as a whole for an area of the metal layer closer to a front surface of the metal layer in a thickness direction of the metal layer.

Accordingly, it becomes possible to improve the reflectance on a front surface of the metal layer and exhibit a high design property.

The addition concentration may become lower as a whole for an area of the metal layer closer to a surface on an opposite side of a front surface of the metal layer in a thickness direction of the metal layer.

Accordingly, it becomes possible to improve the reflectance on the surface on the opposite side of the front surface of the metal layer and exhibit a high design property.

An electronic apparatus according to an embodiment of the present technology includes the decorative film, the casing portion, and an electronic component accommodated in the casing portion.

A decorative film according to an embodiment of the present technology includes a base film and a metal layer.

The metal layer is formed on the base film and includes a first area in which an addition concentration of a predetermined element is relatively high, a second area in which the addition concentration is relatively lower than that of the first area, and minute cracks that are formed using the first area as a reference.

A structure production method according to an embodiment of the present technology includes forming a metal layer to which a predetermined element is added on a base film by vapor deposition.

Minute cracks are formed on the metal layer by stretching the base film.

A decorative film including the metal layer on which the minute cracks are formed is formed.

A transfer film is formed by bonding a carrier film onto the decorative film.

A molded component is formed such that the decorative film is transferred from the transfer film by an in-mold molding method, a hot stamp method, or a vacuum molding method.

In this production method, the metal layer to which the predetermined element is added is formed, and this is stretched to form the minute cracks. Accordingly, aluminum or the like having a high reflectance, for example, can be used as the metal layer. As a result, it becomes possible to produce a structure that is capable of transmitting radio waves while having a metallic appearance and also has a high design property. Further, by adding the predetermined element, it becomes possible to form minute cracks by a low stretching rate. As a result, it becomes possible to suppress a deformation of the base film due to stretching, or the like, and sufficiently suppress an occurrence of defects at a time of producing the structure.

In a structure production method according to another embodiment of the present technology, a transfer film including the metal layer on which the minute cracks are formed is formed. Further, a molded component is formed such that the metal layer peeled off from the base film is transferred by an in-mold molding method, a hot stamp method, or a vacuum molding method.

In a structure production method according to another embodiment of the present technology, a molded component is formed integrally with the decorative film by an insert molding method.

The step of forming the metal layer may include performing vapor deposition while supplying gas including the predetermined element.

Accordingly, it becomes possible to easily form a metal layer to which a predetermined element is added.

The step of forming the minute cracks may include biaxially stretching the base film by a stretching rate of 2% or less in each axial direction.

Since the predetermined element is added, the minute cracks can be formed by a low stretching rate.

The step of forming the metal layer may include performing vacuum vapor deposition on the base film that is conveyed from a feeder roll toward a take-up roll along a circumferential surface of a rotary drum.

By a roll-to-roll method, the decorative film can be mass-produced easily at low costs.

### Advantageous Effects of Invention

As described above, according to the present technology, it is possible to realize a structure that is capable of transmitting radio waves while having a metallic appearance and also has a high design property. It should be noted that the effects described herein are not necessarily limited, and any effect described in the present disclosure may be obtained.

### BRIEF DESCRIPTION OF DRAWINGS

FIG. 1 Schematic diagrams showing a configuration example of a mobile terminal as an electronic apparatus according to one embodiment.

FIG. 2 A schematic cross-sectional diagram showing a configuration example of a metal decorative portion shown in FIG. 1.

FIG. 3 A table including photographs taken by magnifying a surface state of a metal layer using a microscope.

FIG. 4 Diagrams showing a result of analyzing the metal layer using SEM/EDX.

FIG. 5 A schematic diagram showing a configuration example of a vacuum vapor deposition apparatus.

FIG. 6 A schematic diagram showing a configuration example of a biaxial stretching apparatus.

FIG. 7 Schematic diagrams for explaining an in-mold molding method.

FIG. 8 Schematic diagrams for explaining an insert molding method.

FIG. 9 Schematic diagrams showing a configuration example of a transfer film including a base film and the metal layer.

FIG. 10 Cross-sectional diagrams showing a configuration example of a glossy film according to another embodiment.

FIG. 11 A diagram showing a relationship between a thickness of a coating layer formed as a base portion and a pitch of minute cracks.

FIG. 12 A schematic diagram showing a case where front and back sides of a decorative film are reversed and bonded.

### MODES FOR CARRYING OUT THE INVENTION

Hereinafter, embodiments of the present technology will be described with reference to the drawings.

[Configuration of Electronic Apparatus]

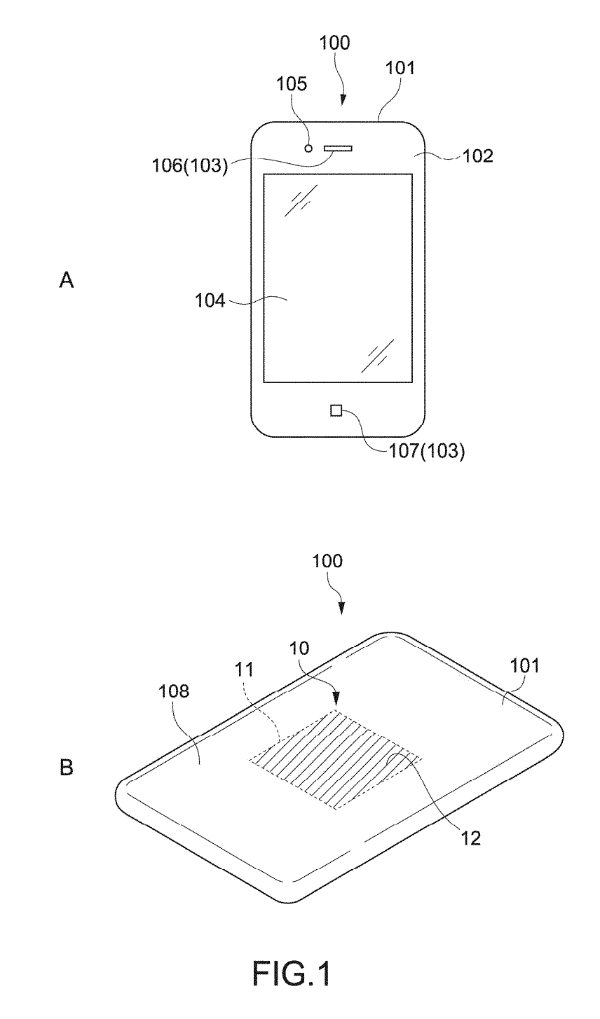

FIG. 1 are schematic diagrams showing a configuration example of a mobile terminal as an electronic apparatus according to an embodiment of the present technology. FIG. 1A is a front view showing a front side of a mobile terminal 100, and FIG. 1B is a perspective view showing a back side of the mobile terminal 100.

The mobile terminal 100 includes a casing portion 101 and electronic components (not shown) accommodated in the casing portion 101. As shown in FIG. 1A, in a front portion 102 which is a front side of the casing portion 101, a phone call portion 103, a touch panel 104, and a face-to-face camera 105 are provided. The phone call portion 103 is provided for talking with a telephone partner and includes a speaker portion 106 and an audio input portion 107. A voice of the telephone partner is output from the speaker portion 106, and a voice of a user is transmitted to the partner side via the audio input portion 107.

Various images and GUIs (Graphical User Interfaces) are displayed on the touch panel 104. The user is capable of viewing a still image or a moving image via the touch panel 104. Further, the user inputs various touch operations via the touch panel 104. The face-to-face camera 105 is used for photographing a face of the user and the like. Specific configurations of the respective devices are not limited.

As shown in FIG. 1B, a metal decorative portion 10 decorated so as to exhibit a metallic appearance is provided on a back surface portion 108 which is a back surface side of the casing portion 101. The metal decorative portion 10 is capable of transmitting radio waves while having a metallic appearance.

Although descriptions will be given later in detail, a to-be-decorated area 11 is set in a predetermined area of the back surface portion 108. A decorative film 12 is bonded to the to-be-decorated area 11, to thus form the metal decorative portion 10. Therefore, the to-be-decorated area 11 becomes an area where the metal decorative portion 10 is formed. By the casing portion 101 including the to-be-decorated area 11 and the decorative film 12 bonded to the to-be-decorated area 11, a structure according to the present technology is formed as a casing component. It should be noted that the structure according to the present technology may be used as a part of the casing component.

In the example shown in FIG. 1B, the metal decorative portion 10 is partially formed at substantially the center of the back surface portion 108. A position at which the metal decorative portion 10 is formed is not limited and may be set as appropriate. For example, the metal decorative portion 10 may be formed on the entire back surface portion 108. Accordingly, it becomes possible to make the entire back surface portion 108 uniformly metallic in appearance.

By making other portions around the metal decorative portion 10 appear substantially the same as the metal decorative portion 10, it also becomes possible to make the entire back surface portion 108 uniformly metallic in appearance. In addition, it is also possible to improve a design property by forming portions other than the metal decorative portion 10 to have other appearances such as woodtone. The position and size of the metal decorative portion 10, the appearance of other portions, and the like only need to be set as appropriate so that a design property that the user desires is exhibited.

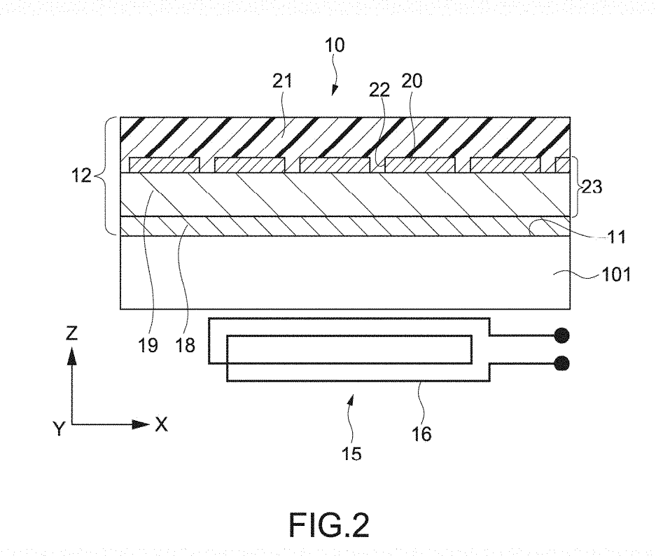

In this embodiment, as the electronic component to be accommodated in the casing portion 101, an antenna portion 15 (see FIG. 2) capable of communicating with an external reader/writer or the like via radio waves is accommodated. The antenna portion 15 includes, for example, a base substrate (not shown), an antenna coil 16 (see FIG. 2) formed on the base substrate, a signal processing circuit portion (not shown) electrically connected to the antenna coil 16, and the like. A specific configuration of the antenna portion 15 is not limited. It should be noted that various electronic components such as an IC chip and a capacitor may be accommodated as the electronic components to be accommodated in the casing portion 101.

FIG. 2 is a schematic cross-sectional diagram showing a configuration example of the metal decorative portion 10. As described above, the metal decorative portion 10 is constituted of the to-be-decorated area 11 set in an area corresponding to the position of the antenna portion 15 and the like and the decorative film 12 bonded to the to-be-decorated area 11.

The decorative film 12 includes an adhesive layer 18, a base film 19, a metal layer 20, and a sealing resin 21. The adhesive layer 18 is a layer for bonding the decorative film 12 to the to-be-decorated area 11. The adhesive layer 18 is formed by applying an adhesive material onto a surface of the base film 19 on the other side of the surface on which the metal layer 20 is formed. A type of the adhesive material, a coating method, and the like are not limited.

The sealing resin 21 is formed of a transparent material and functions as a protection layer (hard coat layer) for protecting the base film 19 and the metal layer 20. The sealing resin 21 is formed by applying, for example, a UV curable resin, a thermosetting resin, a two-component curable resin, or the like. By forming the sealing resin 21, for example, smoothening, antifouling, antistripping, anti-scratch, and the like are achieved. It should be noted that it is also possible to apply an acrylic resin or the like as the protection layer.

The base film 19 is formed of a stretchable material, and a resin film is typically used. As the material of the base film 19, for example, PET (polyethylene terephthalate), PC (polycarbonate), PMMA (polymethyl methacrylate), PP (polypropylene), or the like is used. Other materials may also be used.

The metal layer 20 is formed to make the to-be-decorated area 11 have a metallic appearance. The metal layer 20 is a layer formed on the base film 19 by vacuum vapor deposition, and a large number of minute cracks (hereinafter, referred to as minute cracks) 22 are formed.

By these minute cracks 22, a plurality of discontinuous surfaces are formed in the metal layer 20, and a surface resistance value becomes an almost-insulated state. Therefore, it is possible to sufficiently suppress an occurrence of eddy currents when radio waves hit the casing portion 101. As a result, a reduction of electromagnetic wave energy due to an eddy current loss can be sufficiently suppressed, and high radio wave transmittivity is realized.

A film thickness of the metal layer 20 is set within a range of, for example, 50 nm or more and 300 nm or less. If the film thickness is too small, a reflectance of a visible light area is lowered since light is transmitted, and if the film thickness is too large, the reflectance is lowered since a surface shape is apt to be roughened. Further, the smaller the film thickness, the larger the reflectance reduction amount after a high-temperature high-humidity test (e.g., after 75° C. 90% RH 48 H). It should be noted that RH represents relative humidity.

By setting the film thickness within the range described above in consideration of these points, it was possible to realize a radio wave transmission surface in which a high reflectance is maintained. By setting the film thickness within the range of 50 nm or more and 150 nm or less in particular, a high reflectance was sufficiently maintained, and high radio wave transmittivity was exhibited. Of course, the present technology is not limited to these ranges, and the film thickness of the metal layer 20 may be set as appropriate so that desired characteristics are exhibited. Further, an optimum numerical value range may be set again within the range of 50 nm or more and 300 nm or less, for example.

In this embodiment, when forming the decorative film 12, a glossy film 23 constituted of the base film 19 and the metal layer 20 is formed first. After that, the adhesive layer 18 and the sealing resin 21 are formed on the glossy film 23. It should be noted that the order in which the respective layers are formed is not limited to this. In addition, the adhesive layer 18 and the sealing resin 21 may be omitted depending on molding conditions of the casing portion 101, and the like. In this case, the glossy film 23 is bonded to the to-be-decorated area 11 as the decorative film according to the present technology.

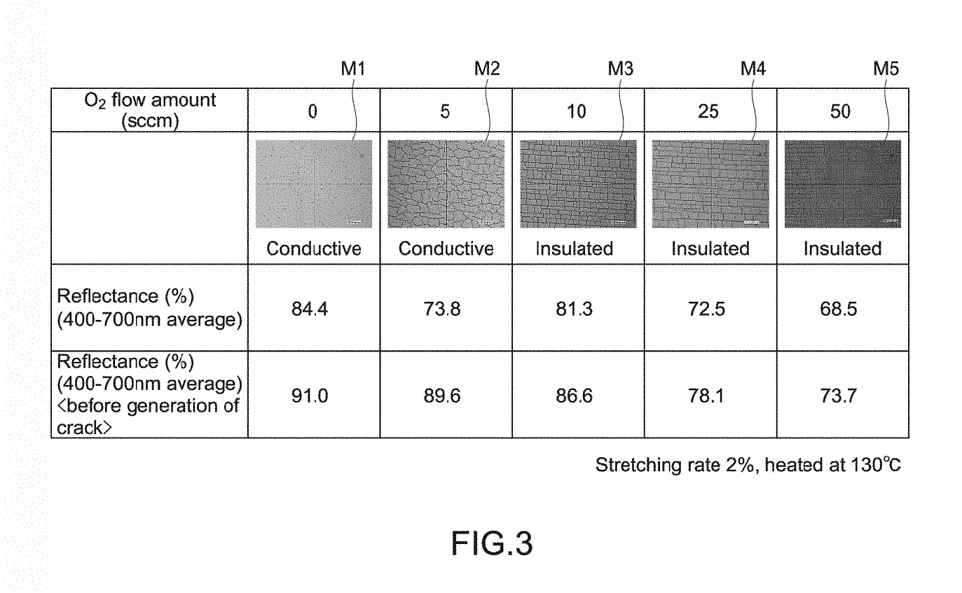

FIG. 3 is a table including photographs obtained by magnifying a surface state of the metal layer 20 of the glossy film 23 using a microscope. In FIG. 3, 5 photographs M1 to M5 are shown, but the surface of the glossy film 23 according to this embodiment is the photograph M3. Other photographs will be described later. It should be noted that there is a preparation to submit color photographs regarding the photographs M1 to M5.

In this embodiment, an aluminum layer to which oxygen is added as a predetermined element is formed as the metal layer 20 on the base film 19 (hereinafter, may be referred to as aluminum layer 20 using same reference numeral). Then, the base film 19 is biaxially stretched under conditions of a stretching rate (stretching amount with respect to original size) of 2% and a substrate heating temperature of 130° C., to thus form the minute cracks 22.

As shown in the photograph M3, the minute cracks 22 are formed to be net-like in the metal layer 20 along biaxial directions. Specifically, the minute cracks 22 are formed so as to intersect with one another along two directions substantially orthogonal to each other. A pitch (crack interval) of the minute cracks 22 in the respective directions is set within a range of, for example, 1 μm or more and 500 μm or less.

For example, if the pitch is too small, light reflected on the surface of the metal layer 20 is scattered or an area of a gap (clearance) having optical transparency is relatively increased, so the reflectance is lowered. On the other hand, if the pitch is too large, the radio wave transmittivity is lowered. By setting the pitch within the range of 1 μm or more and 500 μm or less, it is possible to realize radio wave transmittivity while maintaining a high reflectance. For example, it becomes possible to sufficiently transmit electromagnetic waves (wavelength of about 12.2 cm) of 2.45 GHz of WiFi or Bluetooth (registered trademark).

Of course, the pitch is not limited to this range, and the pitch of the minute cracks 22 may be set as appropriate so that desired characteristics are exhibited. For example, by setting the pitch within a range of 50 μm or more and 200 μm or less, a high reflectance and high radio wave transmittivity were sufficiently exhibited. In addition, an optimum numerical value range may be set again within the range of, for example, 1 μm or more and 500 μm or less.

As shown in the table of FIG. 3, an insulation property was shown when evaluating a surface resistance of the metal layer 20 of the photograph M3 by a four-probe resistor. Further, 81.3% was obtained as a result of measuring a surface reflectance of a visible light area (400 nm to 700 nm) using a spectrophotometer (U-4100 manufactured by Hitachi, Ltd.). In other words, it has become possible to realize the metal layer 20 that includes a metallic luster surface having a high reflectance and has sufficient radio wave transmittivity.

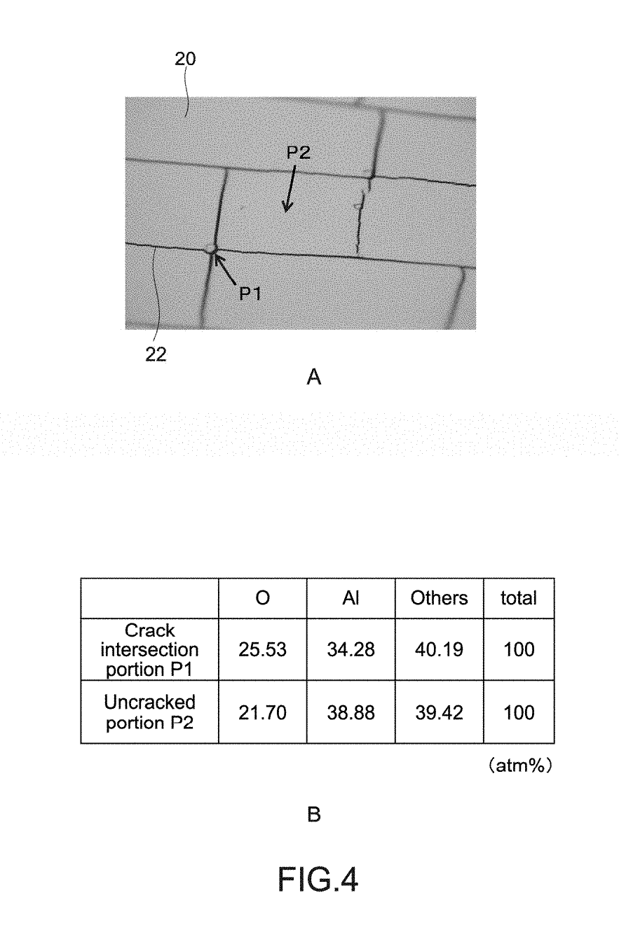

FIG. 4 are diagrams showing a result of analyzing the metal layer 20 using SEM/EDX (scanning electron microscope/energy-dispersive X-ray spectroscopy). FIG. 4A is an image of the surface acquired by SEM. FIG. 4B shows a composition ratio of constituent elements at points P1 and P2 shown in FIG. 4A.

As shown in FIG. 4B, a ratio of added oxygen is relatively high at the point P1 of a portion where the minute cracks 22 intersect. The term relatively means as compared with the point P2 of a portion where there are no minute cracks 22. It should be noted that the composition ratio of “others” is mainly a composition ratio of constituent elements included in the base film 19. Oxygen may be included in the base film 19, but a ratio thereof is equal at the points P1 and P2. Therefore, in the metal layer 20, the point P1 has a higher oxygen ratio.

As described above, the inventors of the present invention have found that, regarding the glossy film 23 produced by a method according to the present technology to be described below, an area where an oxygen addition concentration is relatively high (first area) and an area where the oxygen addition concentration is relatively low (second area) are included in the metal layer 20. In other words, it was found that an area having a locally-high oxygen density is generated. In the example shown in FIG. 4, the area including the point P1 becomes the first area, and the area including the point P2 becomes the second area. Further, it was also found that the minute cracks 22 are formed using the first area as a reference. As far as we can tell, it is considered that a tensile breakage intensity becomes lower as the oxygen addition concentration increases.

It should be noted that the minute crack 22 is formed starting from a certain point in the first area, and that crack extends along the biaxial directions. Of course, the extending cracks may intersect with each other. In other words, not all the intersections of the minute cracks 22 are included in the first area. However, at least a part of the intersections (may be one intersection) is included in the first area where the oxygen addition concentration is high.

Formation of the minute cracks 22 using the first area as a reference includes the fact that at least a part of the intersections of the minute cracks 22 as described above is included in the first area, for example. Of course, the present technology is not limited to this, and other situations where an arbitrary point of the first area becomes as a starting point for forming the minute cracks 22 are included in the formation of the minute cracks 22 using the first area as a reference. For example, a crack width of the minute cracks 22 in the first area is relatively larger than that of the cracks in the second area, and the like.

It should be noted that it is difficult to extract other points as the structure or characteristics unique to the glossy film 23 produced by the method according to the present technology, and it is considered not practical. Further, for the glossy film 23 produced by the method according to the present technology, regarding whether the characteristic points described above are fully and constantly generated, the possibility that the characteristic points will not be generated depending on production conditions and the like is undeniable.

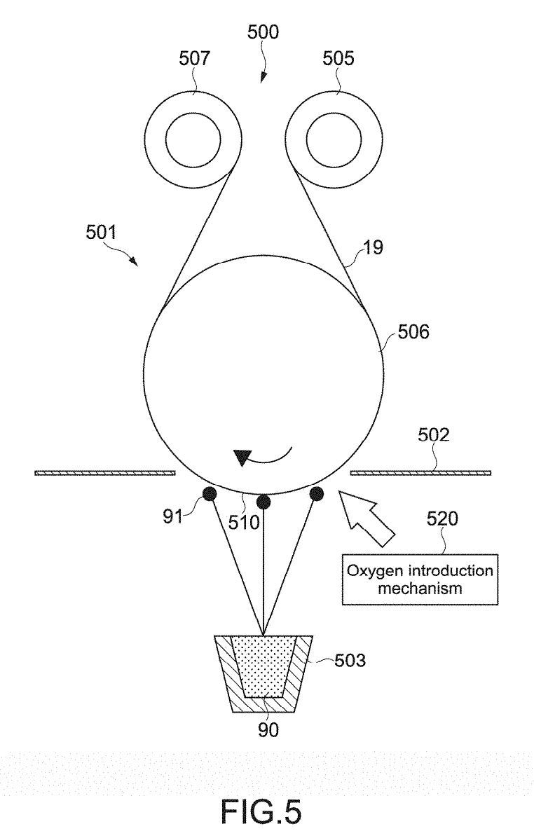

FIG. 5 is a schematic diagram showing a configuration example of a vacuum vapor deposition apparatus. A vacuum vapor deposition apparatus 500 includes a film conveyor mechanism 501 arranged inside a vacuum chamber (not shown), a partition wall 502, a crucible 503, a heating source (not shown), and an oxygen introduction mechanism 520.

The film conveyor mechanism 501 includes a feeder roll 505, a rotary drum 506, and a take-up roll 507. The base film 19 is conveyed from the feeder roll 505 toward the take-up roll 507 along a circumferential surface of the rotary drum 506.

The crucible 503 is arranged at a position opposing the rotary drum 506. In the crucible 503, aluminum 90 is accommodated as a metal material configuring the metal layer 20. An area of the rotary drum 506 opposing the crucible 503 becomes a deposition area 510. The partition wall 502 restricts fine particles 91 of the aluminum 90 that proceed at angles directed toward areas other than the deposition area 510. The oxygen introduction mechanism 520 is arranged on an upstream side (feeder roll 505 side) of the deposition area 510. An arbitrary apparatus may be used as the oxygen introduction mechanism 520.

The base film 19 is conveyed in a state where the rotary drum 506 is sufficiently cooled. Oxygen is blown toward the base film 19 by the oxygen introduction mechanism 520. The oxygen supplied by the oxygen introduction mechanism 520 corresponds to gas including a predetermined element. In accordance with the supply of oxygen, the aluminum 90 in the crucible 503 is heated by a heating source (not shown) such as a heater, a laser, and an electron gun. As a result, vapor including the fine particles 91 is generated from the crucible 503.

The fine particles 91 of the aluminum 90 included in the vapor are deposited on the base film 19 proceeding to the deposition area 510, whereby the aluminum layer 20 to which oxygen is added is formed on the base film 19. Since continuous vacuum vapor deposition by a roll-to-roll method is possible in this embodiment, a significant cost reduction and improvement of productivity can be achieved. Needless to say, the present technology is also applicable to a case where a batch-type vacuum vapor deposition apparatus is used.

Since the oxygen supply device 520 is arranged on the upstream side, an amount of oxygen added to the metal layer 20 formed on the base film 19 on the upstream side of the deposition area 510 becomes large. On the other hand, the amount of oxygen added to the metal layer 20 formed on the downstream side becomes small. Therefore, the oxygen addition concentration of the metal layer 20 becomes lower as a whole in the area closer to the surface in the thickness direction of the metal layer 20. As a result, it becomes possible to improve the reflectance of the visible light area on the surface of the metal layer 20 and thus realize a metallic luster having a high design property.

It should be noted that even in a case where the oxygen addition concentration is differentiated as a whole in the thickness direction of the metal layer 20, there is no influence on the fact that the first area having a high addition concentration and the second area having a low addition concentration are formed in the metal layer 20. The minute cracks 22 are appropriately formed using the first area as a reference.

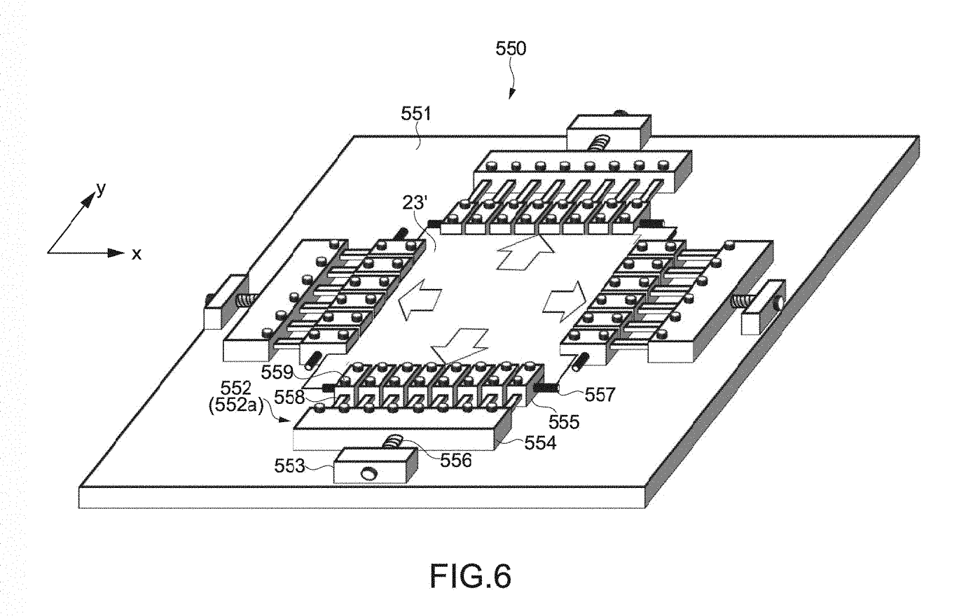

FIG. 6 is a schematic diagram showing a configuration example of a biaxial stretching apparatus. A biaxial stretching apparatus 550 includes a base member 551 and 4 stretching mechanisms 552 that are arranged on the base member 551 and have substantially the same configuration. The 4 stretching mechanisms 552 are arranged two each on the two axes orthogonal to each other (x axis and y axis) while opposing one another on the respective axes. Hereinafter, descriptions will be given while referring to the stretching mechanism 552a that stretches a glossy film 23′ in a direction opposite to that of the arrow in the y-axis direction.

The stretching mechanism 552a includes a fixed block 553, a movable block 554, and a plurality of clips 555. The fixed block 553 is fixed to the base member 551. An stretching screw 556 extending in a stretching direction (y direction) penetrates through the fixed block 553.

The movable block 554 is movably arranged on the base member 551. The movable block 554 is connected to the stretching screw 556 penetrating the fixed block 553. Accordingly, by operating the stretching screw 556, the movable block 554 becomes movable in the y direction.

The plurality of clips 555 are arranged along a direction orthogonal to the stretching direction (x direction). A slide shaft 557 extending in the x direction penetrates through each of the plurality of clips 555. A position of each of the clips 555 in the x direction can be changed along the slide shaft 557. Each of the plurality of clips 555 and the movable block 554 are coupled by coupling links 558 and coupling pins 559.

The stretching rate is controlled by an operation amount of the stretching screw 556. Further, the stretching rate can also be controlled by appropriately setting the number and positions of the plurality of clips 555, the length of the coupling links 558, and the like. It should be noted that the configuration of the biaxial stretching apparatus 550 is not limited. The biaxial stretching apparatus 550 according to this embodiment biaxially stretches a film with a full cut sheet, but is also capable of biaxially stretching continuously with a roll. For example, continuous biaxial stretching becomes possible by applying a tension in a traveling direction between the rolls and a tension that forms a right angle to the traveling direction by the clips 555 moving in synchronization with the traveling, that are provided between the rolls.

The glossy film 23′ obtained after the vacuum vapor deposition is placed on the base member 501, and the plurality of clips 555 of the stretching mechanisms 552 are respectively attached to the 4 sides. In a state where the glossy film 23′ is heated by a temperature-controlled heating lamp (not shown) or temperature controlled hot air, the 4 stretching screws 556 are operated to perform biaxial stretching. In this embodiment, the base film 19 is biaxially stretched under the conditions of a stretching rate of 2% in the respective axis directions and a substrate heating temperature of 130° C. As a result, as shown in FIG. 3, the net-like minute cracks 22 are formed along directions (biaxial directions) orthogonal to the stretching direction.

If the stretching rate is too low, appropriate minute cracks 22 are not formed, and thus the metal layer 20 will become conductive. In this case, due to an influence of eddy currents or the like, sufficient radio wave transmittivity is not exhibited. On the other hand, if the stretching rate is too large, a damage to the base film 19 after stretching becomes large. As a result, when bonding the decorative film 12 to the to-be-decorated area 11, there is a possibility that a yield will be deteriorated due to entrainment of air, wrinkling, and the like. Further, due to the deformation of the base film 19 or the metal layer 20 itself, the design property of the metal decorative portion 10 may be lowered. This problem may also occur in a case where the metal layer 20 is peeled off from the base film 19 and transferred.

In the glossy film 23 according to this embodiment, the minute cracks 22 can be appropriately formed with a low stretching rate of 2% or less in the respective axial directions. As a result, the base film 19 can be sufficiently prevented from being damaged, and the yield can be improved. Further, the design property of the metal decorative portion 10 to which the decorative film 12 is bonded can be maintained high. Of course, the stretching rate can be set as appropriate, and the stretching rate of 2% or more may be set as long as the defects described above do not occur.

The table shown in FIG. 3 shows the photographs in a case where oxygen introduction amounts (flow rate: sccm) are differentiated as the condition for forming the metal layer 20. As shown in the photograph M1, in a case where the flow rate of oxygen is 0 sccm, minute cracks 22 were hardly generated with the stretching rate of 2%, and the metal layer 20 having conductivity on the surface was formed (surface resistance value: about 2Ω/□). On the other hand, since no oxygen is added, the reflectance obtained before and after the stretching process were as high as 91.0% and 84.4%, respectively.

As shown in the photograph M2, in a case where the flow rate of oxygen is 5 sccm, minute cracks 22 were formed by biaxial stretching with the stretching rate of 2%, but cracks enough to form a discontinuous surface were not formed. Therefore, the surface showed conductivity. The reflectance was 89.6% and 73.8% before and after the stretching process.

As shown in the photograph M3, in a case where the flow rate of oxygen is 10 sccm, minute cracks 22 were appropriately formed by biaxial stretching at a stretching rate of 2%, and the surface was in an insulated state. Further, the reflectance was 86.6% and 81.3% before and after the stretching process. In this way, a high reflectance and sufficient radio wave transmittivity can be exhibited. It should be noted that when the minute cracks 22 are formed, light is transmitted through the gaps of the minute cracks 22, so the reflectance is lowered by about 5%.

As shown in the photograph M4, in a case where the flow rate of oxygen is 25 sccm, the surface becomes an insulated state by the minute cracks 22. The reflectance was 78.1% and 72.5% before and after the stretching process. Also in a case where the flow rate of oxygen is 50 sccm, the surface becomes an insulated state, and the reflectance was 73.7% and 68.5% before and after the stretching process.

By increasing the flow rate of oxygen and increasing the oxygen addition concentration (increasing addition amount) in this way, it becomes possible to appropriately form the minute cracks 22 by biaxial stretching at a stretching rate of 2%. On the other hand, when the flow rate of oxygen is increased, the ratio of aluminum becomes low, so the reflectance is lowered. For example, an oxygen supply amount is set as appropriate within a range from an amount with which the surface of the metal layer 20 becomes an insulated state to an amount with which the reflectance after the stretching process becomes smaller than 70%. Of course, more oxygen may be supplied in a case where the reflectance may be less than 70% or in a case where the reflectance is wished to be suppressed. The oxygen supply amount may be set as appropriate within a range up until the metal layer 20 becomes an oxide film by oxygen.

It should be noted that in the example shown in FIG. 3, in a case where the flow rate of oxygen is 5 sccm, the reflectance after the stretching process is lower than that of a tendency. It is considered that this is because the first area where the cracks can be generated by low stretching is not sufficiently formed, and cracks are forcibly generated in an area where the tensile breakage intensity is not suppressed. Specifically, it is considered that surface flatness is impaired by incomplete minute cracks, and a measurement value of a spectrophotometer is lowered due to diffused reflection or the like. Also from this point, it can be seen that it is important to set the oxygen supply amount within an appropriate range.

When the protection layer such as an adhesive resin and a hard coat layer is formed, the surface reflectance decreases by about 5%. Also taking this into consideration, by using the decorative film 12 according to the present technology, it becomes possible to increase the surface reflectance to a high value of 65% or more in a state where the protection layer is formed.

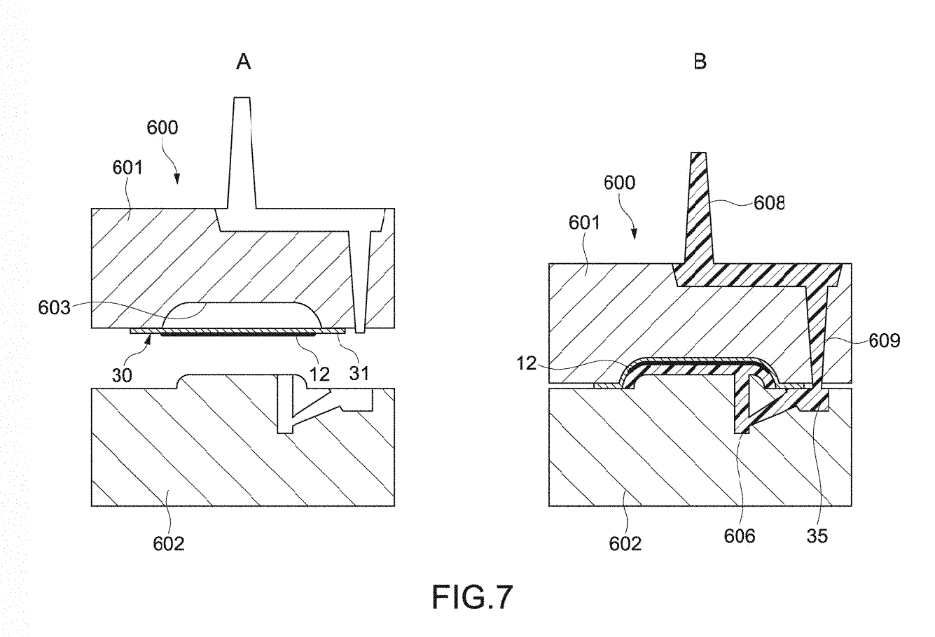

FIG. 7 are schematic diagrams for explaining the in-mold molding method. The in-mold molding is performed by a molding apparatus 600 including a cavity mold 601 and a core mold 602 as shown in FIG. 7. As shown in FIG. 7A, a concave portion 603 corresponding to the shape of the casing portion 101 is formed in the cavity mold 601. A transfer film 30 is arranged so as to cover this concave portion 603. The transfer film 30 is formed by bonding the decorative film 12 shown in FIG. 2 to a carrier film 31. The transfer film 30 is supplied from outside the molding apparatus 600 by, for example, a roll-to-roll method.

As shown in FIG. 7B, the cavity mold 601 and the core mold 602 are clamped, and a molding resin 35 is injected into the concave portion 603 via a gate portion 606 formed in the core mold 602. In the cavity mold 601, a sprue portion 608 to which the molding resin 35 is supplied and a runner portion 609 coupled to the sprue portion 608 are formed. When the cavity mold 601 and the core mold 602 are clamped, the runner portion 609 and the gate portion 606 are coupled. As a result, the molding resin 35 supplied to the sprue portion 608 is injected into the concave portion 603. It should be noted that the configuration for injecting the molding resin 35 is not limited.

As the molding resin 35, a general-purpose resin such as an ABS (acrylonitrile butadiene styrene) resin, engineering plastics such as a PC resin and a mixed resin of ABS and PC, or the like is used. The present technology is not limited to this, and the material and color (transparency) of the molding resin may be selected as appropriate so that a desired casing portion (casing component) is obtained.

The molding resin 35 is injected into the concave portion 603 while being melted at a high temperature. The molding resin 35 is injected so as to press an inner surface of the concave portion 603. At this time, the transfer film 30 arranged in the concave portion 603 is pressed by the molding resin 35 to be deformed. The adhesive layer 18 formed on the transfer film 30 is melted by the heat of the molding resin 35, and the decorative film 12 is bonded to the surface of the molding resin 35.

After the molding resin 35 is injected, the cavity mold 601 and the core mold 602 are cooled, and the clamp is released. The molding resin 35 onto which the decorative film 12 is transferred is adhered to the core mold 602. By taking out the molding resin 35, the casing portion 101 in which the metal decorative portion 10 is formed in a predetermined area is produced. It should be noted that the carrier film 31 is peeled off when the clamp is released.

By using the in-mold molding method, positioning of the decorative film 12 becomes easy, and the metal decorative portion 10 can be formed with ease. Further, a degree of freedom in designing the shape of the casing portion 101 is high, and thus it is possible to produce casing portions 101 of various shapes.

It should be noted that the antenna portion 15 accommodated inside the casing portion 101 may be attached by the in-mold molding method at the time of molding the casing portion 101. Alternatively, the antenna portion 15 may be attached to the inner side of the casing portion 101 after the casing portion 101 is molded. Further, the antenna portion 15 may be built in the casing portion 101.

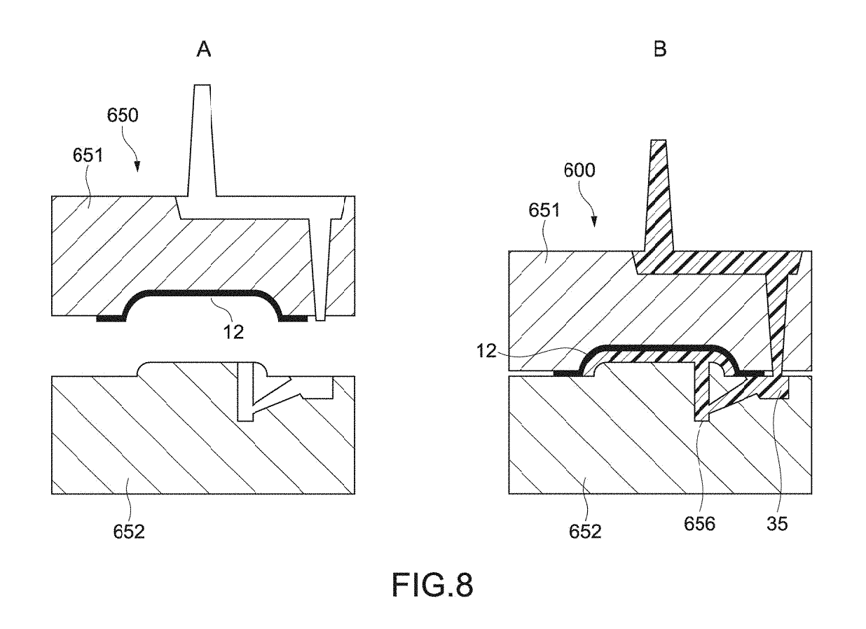

FIG. 8 are schematic diagrams for explaining the insert molding method. In the insert molding, the decorative film 12 is arranged as an insert film in a cavity mold 651 of a molding apparatus 650. Then, as shown in FIG. 8B, the cavity mold 651 and a core mold 652 are clamped, and the molding resin 35 is injected into the cavity mold 651 via a gate portion 656. As a result, the casing portion 101 is formed integrally with the decorative film 12. It is also possible to easily form the metal decorative portion 10 by using the insert molding method. Further, the casing portions 101 of various shapes can be produced. It should be noted that the configuration of the molding apparatus that executes the in-mold molding and the insert molding is not limited.

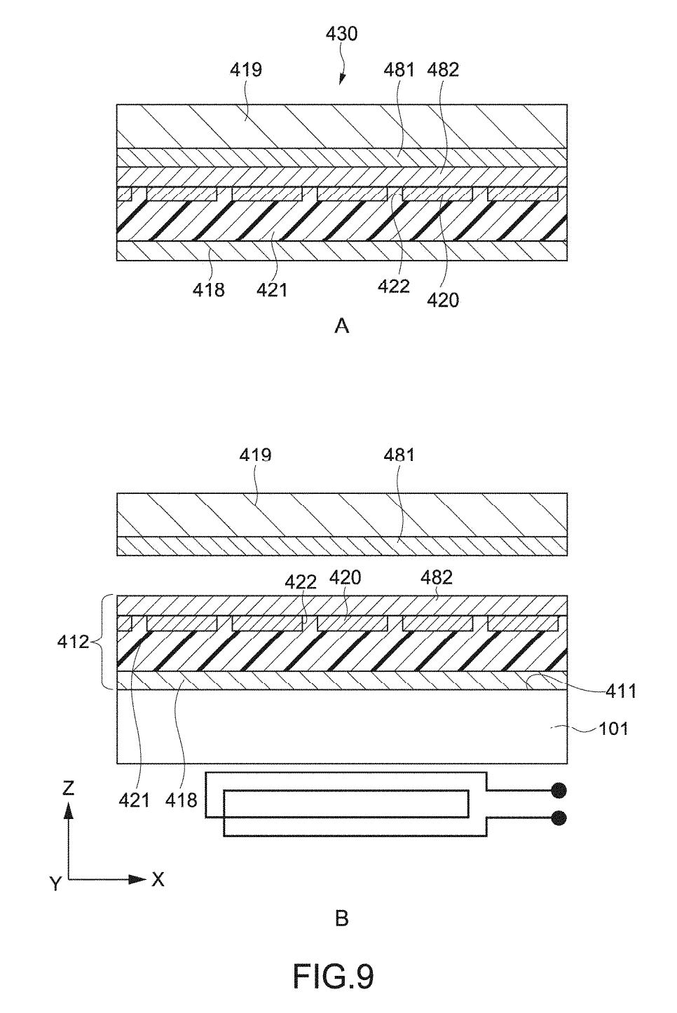

FIG. 9 are schematic diagrams showing a configuration example of a transfer film including a base film and a metal layer. This transfer film 430 includes a base film 419, a release layer 481, a hard coat layer 482, a metal layer 420, an adhesive resin 421, and an adhesive layer 418. The release layer 481 and the hard coat layer 482 are formed on the base film 419 in this order.

Therefore, the metal layer 420 is formed on the base film 419 on which the release layer 481 and the hard coat layer 482 are formed. Then, the base film 419 is stretched to form minute cracks 422 in the metal layer 420.

As shown in FIG. 9B, when the casing portion 101 is formed by the in-mold molding method, the base film 419 and the release layer 481 are peeled off, and the decorative film 412 including the metal layer 420 is bonded to a to-be-decorated area 411. In this way, the base film 419 may be used as a carrier film. It should be noted that the base film 419 on which the release layer 481 is formed can also be regarded as the base film according to the present technology.

It is also possible to form the casing portion 101 in which the decorative film 12 including the metal layer 20 is transferred onto the to-be-decorated area 11 by a hot stamp method using the transfer films 30 and 430 shown in FIGS. 7 and 9. In addition, the decorative film 12 may be bonded to the casing portion 101 by an arbitrary method such as pasting. Moreover, vacuum molding, pressure molding, or the like may also be used.

As described above, in the casing portion 101 (casing component) as the structure according to this embodiment, oxygen is added to the metal layer 20, and the minute cracks 22 are formed using the first area having a relatively-high addition concentration as a reference. Accordingly, it becomes possible to form the metal layer 20 with aluminum or the like having a high reflectance, for example. As a result, it becomes possible to realize the casing portion 101 that is capable of transmitting radio waves while having a metallic appearance and also has a high design property.

Silver (Ag) may be used instead of aluminum. Also in this case, it becomes possible to appropriately form the minute cracks 22 at a stretching rate of 2% or less by adding oxygen, and thus realize the metal layer 20 having a reflectance of 70% or more.

The element to be added is not limited to oxygen, and nitrogen (N) may be added instead, for example. For example, a nitrogen introduction mechanism may be arranged in place of the oxygen introduction mechanism 520 shown in FIG. 5, and nitrogen may be blown as introduction gas. For example, a supply amount only needs to be set as appropriate within a range from an addition amount with which a surface of a metal film after the stretching process becomes an insulated state to a point at which the metal layer is nitrided. It should be noted that other elements may also be added.

In a case where a thin film having an island-like structure of In or Sn is used as the metal film that transmits radio waves, the reflectance is as low as about 50% to 60%. This is due to an optical constant of the material, and it is extremely difficult to realize the reflectance of 70% or more like the glossy film 23 according to this embodiment. In addition, since In is rare metal, material costs become high.

Further, also in a case of generating cracks in a metal film formed of nickel, copper, or the like by performing after-baking using non-electrolytic plating, it is difficult to realize the reflectance of 70% or more. Furthermore, while it is also possible to alloy a silicon and metal to increase surface resistivity to generate radio wave transmittivity, also in this case, it is difficult to realize the reflectance of 70% or more.

In addition, in this embodiment, since the film of the metal material is formed by vacuum vapor deposition, a material such as Al and Ti that is difficult to be deposited on the resin can be used in wet plating such as non-electrolytic plating. Therefore, a selection range of usable metal materials is extremely wide, and a metal material having a high reflectance can be used. Further, since minute cracks 22 are formed by biaxial stretching, it becomes possible to form the metal layer 20 with high adhesion in the vacuum vapor deposition. As a result, the metal layer 20 does not fall during the in-mold molding or insert molding, and the casing portion 101 can be molded appropriately. In addition, durability of the metal decorative portion 10 itself can also be improved.

Further, in this embodiment, the glossy film 23 can be realized with only a single layer film of metal. Therefore, since it becomes possible to use a simple vapor deposition process by a simple configuration of a vapor deposition source, apparatus costs and the like can be suppressed. It should be noted that the method of forming the metal layer to which oxygen or nitrogen is added is not limited to the case where gas is blown toward the film conveyor mechanism 501. For example, oxygen or the like may be incorporated into the metal material in the crucible.

The present technology is applicable to almost all electronic apparatuses that incorporate built-in antennas or the like therein. Various examples of such an electronic apparatus include electronic apparatuses such as a cellular phone, a smartphone, a personal computer, a game machine, a digital camera, an audio apparatus, a TV, a projector, a car navigation system, a GPS terminal, a digital camera, and a wearable information apparatus (glasses type or wristband type), operation apparatuses such as a remote controller, a mouse, and a touch pen that operate these apparatuses by wireless communication or the like, electronic apparatuses mounted on vehicles, such as an in-vehicle radar and an in-vehicle antenna, and the like. Further, the present technology is also applicable to an IoT apparatus connected to the Internet and the like.

Further, the present technology is not limited to the casing component of an electronic apparatus and the like, and is also applicable to vehicles and architectural structures. Specifically, a structure including a decorative portion according to the present technology and a member including a to-be-decorated area to which the decorative portion is to be bonded may be used as a part or all of the vehicle or architectural structure. Accordingly, it becomes possible to realize a vehicle or architectural structure including a wall surface or the like that is capable of transmitting radio waves while having a metallic appearance, and exhibit an extremely-high design property. It should be noted that the vehicle includes arbitrary vehicles such as an automobile, a bus, and a train. The architectural structure includes arbitrary architectural structures such as a single-family house, complex housing, a facility, and a bridge.

### Other Embodiments

The present technology is not limited to the embodiment described above, and various other embodiments can be realized.

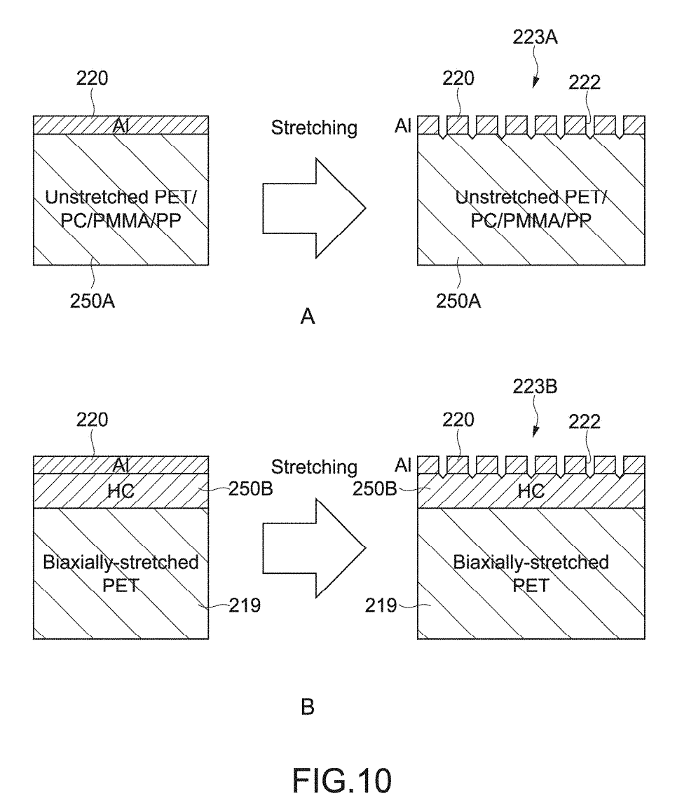

FIG. 10 are cross-sectional diagrams each showing a configuration example of a glossy film according to another embodiment. In this glossy film 223, a base portion 250 having a tensile breakage intensity than a metal layer 220 is provided as a member that supports the metal layer 220. Accordingly, it becomes possible to lower the stretching rate requisite for forming the minute cracks 222. For example, it is also possible to form the minute cracks 222 with a stretching rate smaller than that requisite for breaking the metal layer 220 itself. It is considered that this is because the metal layer 220 breaks following a breakage of surfaces of base portions 250A and B having a small tensile breakage intensity as shown in FIGS. 10A and 10B.

As shown in FIG. 10A, a base film having a small tensile breakage intensity may be used as the base portion 250A. For example, a biaxially-stretched PET has a tensile breakage intensity of about 200 to about 250 MPa, which often becomes higher than the tensile breakage intensity of the aluminum layer 220.

Meanwhile, the tensile breakage intensities of an unstretched PET, PC, PMMA, and PP are as follows.

Unstretched PET: about 70 MPa

PC: about 69 to about 72 MPa

PMMA: about 80 MPa

PP: about 30 to about 72 MPa

Therefore, by using the base film formed of these materials as the base portion 250A, it is possible to appropriately form the minute cracks 222 with a low stretching rate.

As shown in FIG. 10B, a coating layer may be formed on the base film 219 as the base portion 250B. For example, by applying an acrylic resin or the like to form a hard coat layer, the hard coat layer can be easily formed as the base portion 250B.

By forming the coating layer having a small tensile breakage intensity between the base film 219 having a large tensile breakage intensity and the metal layer 220, formation of the minute cracks 222 at a low stretching rate can be realized while maintaining durability of the glossy film 223B high. Further, this is also effective in a case where the PET needs to be used in terms of the production process, and the like. It should be noted that the breakage of the surfaces of the base film and the hard coat layer that function as the base portions 250A and 250B shown in FIGS. 10A and 10B is extremely small, which is about a width of the minute cracks 222. Therefore, this does not cause entrainment of air, lowering of a design property, and the like.

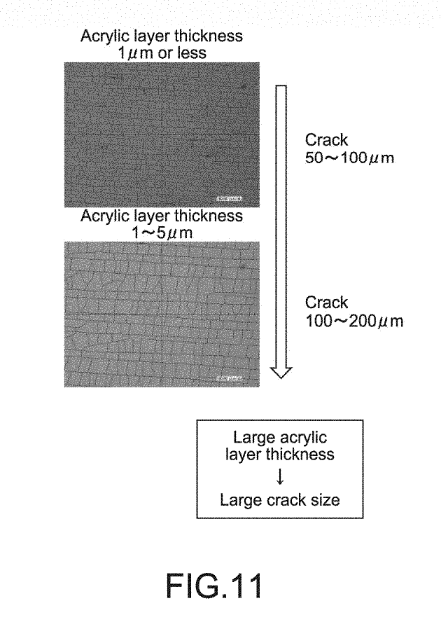

FIG. 11 is a diagram showing a relationship between a thickness of the coating layer formed as the base portion 250B and a pitch (crack interval) of the minute cracks 222 formed in the metal layer 220. FIG. 11 shows the relationship in a case where an acrylic layer is formed as the coating layer.

As shown in FIG. 11, in a case where the thickness of the acrylic layer is 1 μm or less, the pitch of the minute cracks 222 was 50 μm to 100 μm. On the other hand, when the thickness of the acrylic layer is set within the range of 1 μm to 5 μm, the pitch of the minute cracks 222 was 100 μm to 200 μm. In this way, it was found that the pitch of the minute cracks 222 becomes larger as the thickness of the acrylic layer becomes larger. Therefore, the pitch of the minute cracks 222 can be adjusted by controlling the thickness of the acrylic layer as appropriate. For example, by setting the thickness of the acrylic layer within the range of 0.1 μm or more and 10 μm or less, it is possible to adjust the thickness of the minute cracks 222 within a desired range. Of course, the thickness is not limited to this range, and an optimum numerical value range may be set again within the range of 0.1 μm or more and 10 μm or less, for example.

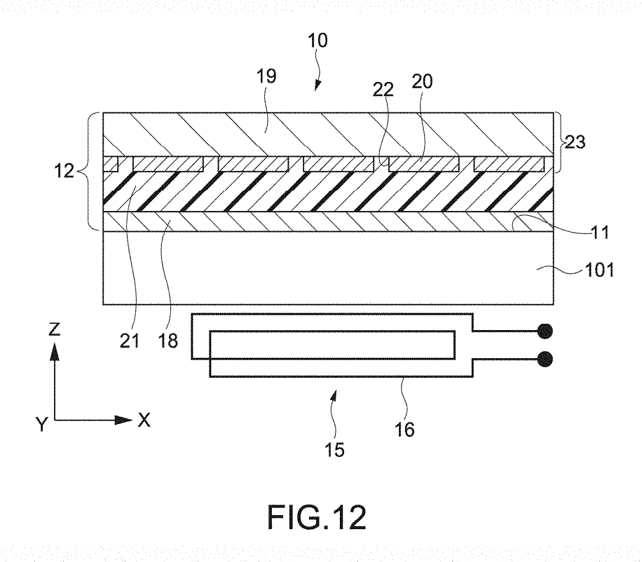

As shown in FIG. 2, in this embodiment, the base film 19 and the casing portion 101 are bonded via the adhesive layer 18. The present technology is not limited to this, and the sealing resin 21 side may be bonded to the casing portion 101 as shown in FIG. 12. In this case, a transparent base film 19 may be used, and the sealing resin 21 may be opaque. In other words, an arbitrary colored resin may be used as the sealing resin 21. Accordingly, the design property can be improved. Further, it is also possible to make the base film 19 function as the protection layer.

Furthermore, in a case where the configuration shown in FIG. 12 is adopted, the glossy film 23 may be formed such that the oxygen addition concentration becomes lower as a whole for the area of the metal layer 20 closer to a surface on an opposite side of the front surface of the metal layer 20 in the thickness direction of the metal layer 20. The front surface of the metal layer 20 corresponds to a vapor deposition termination surface, and the surface on the opposite side corresponds to a vapor deposition start surface. In this embodiment, the surface that can be visually recognized via the transparent base film 19 corresponds to the surface on the opposite side of the front surface of the metal layer 20.

By setting the oxygen addition concentration to become lower as a whole in the area closer to the base film 19-side surface, the reflectance of the visible light area on that surface can be improved, and a metallic luster of a high design property can be realized. It should be noted that in the vacuum vapor deposition apparatus 500 shown in FIG. 5, it is possible to easily set the addition concentration to become lower as a whole in the area closer to the base film 19-side surface by arranging the oxygen introduction mechanism 520 on a downstream side (take-up roll 507 side) of the deposition area 510.

The stretching for forming the minute cracks 22 is not limited to biaxial stretching. Uniaxial stretching or stretching of 3 or more axes may be executed. Further, the biaxial stretching may be further executed by the roll-to-roll method on the base film 19 taken up by the take-up roll 507 shown in FIG. 5. Furthermore, after the vacuum vapor deposition is further performed, the biaxial stretching may be executed before the take up by the take-up roll 507.

At least two of the feature portions according to the present technology described above can be combined. In other words, various feature portions described in the respective embodiments may be arbitrarily combined without distinguishing the embodiments from one another. Moreover, the various effects described above are mere examples and should not be limited thereto, and other effects may also be exerted.

It should be noted that the present technology can also take the following configurations.

(1) A structure, including:

a decorative film including a metal layer that includes a first area in which an addition concentration of a predetermined element is relatively high, a second area in which the addition concentration is relatively lower than that of the first area, and minute cracks that are formed using the first area as a reference; and

a casing portion including a to-be-decorated area to which the decorative film is to be bonded.

(2) The structure according to (1), in which

the predetermined element is oxygen or nitrogen.

(3) The structure according to (1) or (2), in which

the metal layer is formed of aluminum or silver.

(4) The structure according to any one of (1) to (3), in which

the metal layer has a thickness of 50 nm or more and 300 nm or less.

(5) The structure according to any one of (1) to (4), in which

a pitch of the minute cracks is within a range of 1 μm or more and 500 μm or less.

(6) The structure according to any one of (1) to (5), in which

a surface reflectance of a visible light area of the metal layer is 70% or more.

(7) The structure according to any one of (1) to (6), in which

the decorative film includes a protection layer laminated on the metal layer, and a surface reflectance of a visible light area of the protection layer is 65% or more.

(8) The structure according to any one of (1) to (7), in which

the minute cracks are formed to have a net-like appearance.

(9) The structure according to (8), in which

at least one intersection of the minute cracks is included in the first area.

(10) The structure according to any one of (1) to (9), in which

the decorative film includes a base portion that supports the metal layer, a tensile breakage intensity of the base portion being smaller than that of the metal layer.

(11) The structure according to (10), in which

the base portion is a base film.

(12) The structure according to (10), in which

the base portion is a coating layer formed on a base film.

(13) The structure according to any one of (1) to (12), in which

the addition concentration becomes lower as a whole for an area of the metal layer closer to a front surface of the metal layer in a thickness direction of the metal layer.

(14) The structure according to any one of (1) to (12), in which

the addition concentration becomes lower as a whole for an area of the metal layer closer to a surface on an opposite side of a front surface of the metal layer in a thickness direction of the metal layer.

(15) An electronic apparatus, including:

a decorative film including a metal layer that includes a first area in which an addition concentration of a predetermined element is relatively high, a second area in which the addition concentration is relatively lower than that of the first area, and minute cracks that are formed using the first area as a reference;

a casing portion including a to-be-decorated area to which the decorative film is to be bonded; and

an electronic component accommodated in the casing portion.

(16) A decorative film, including:

a base film; and

a metal layer that is formed on the base film and includes a first area in which an addition concentration of a predetermined element is relatively high, a second area in which the addition concentration is relatively lower than that of the first area, and minute cracks that are formed using the first area as a reference.

(17) A structure production method, including:

forming a metal layer to which a predetermined element is added on a base film by vapor deposition;

forming minute cracks on the metal layer by stretching the base film;

forming a decorative film including the metal layer on which the minute cracks are formed;

forming a transfer film by bonding a carrier film onto the decorative film; and

forming a molded component such that the decorative film is transferred from the transfer film by an in-mold molding method, a hot stamp method, or a vacuum molding method.

(18) A structure production method, including:

forming a metal layer to which a predetermined element is added on a base film by vapor deposition;

forming minute cracks on the metal layer by stretching the base film;

forming a transfer film including the metal layer on which the minute cracks are formed; and

forming a molded component such that the metal layer peeled off from the base film is transferred by an in-mold molding method, a hot stamp method, or a vacuum molding method.

(19) A structure production method, including:

forming a metal layer to which a predetermined element is added on a base film by vapor deposition;

forming minute cracks on the metal layer by stretching the base film;

forming a decorative film including the metal layer on which the minute cracks are formed; and

forming a molded component integrally with the decorative film by an insert molding method.

(20) The structure production method according to any one of (17) to (19), in which

the step of forming the metal layer includes performing vapor deposition while supplying gas including the predetermined element.

(21) The structure production method according to any one of (17) to (20), in which

the step of forming the minute cracks includes biaxially stretching the base film by a stretching rate of 2% or less in each axial direction.

(22) The structure production method according to any one of (17) to (21), in which

the step of forming the metal layer includes performing vacuum vapor deposition on the base film that is conveyed from a feeder roll toward a take-up roll along a circumferential surface of a rotary drum.

### REFERENCE SIGNS LIST

P1 point where oxygen addition concentration is high
P2 point where oxygen addition concentration is low
10 metal decorative portion
11, 411 to-be-decorated area
12, 412 decorative film
15 antenna portion
19, 219, 419 base film
20, 220, 420 metal layer (aluminum layer)
22, 222, 422 minute crack
23, 223 glossy film
30, 430 transfer film
31 carrier film
90 aluminum
100 mobile terminal
101 casing portion
250A, B base portion
482 hard coat layer
500 vacuum vapor deposition apparatus
501 film conveyor mechanism
510 deposition area
520 oxygen introduction mechanism
550 biaxial stretching apparatus
600, 650 molding apparatus

1. A structure, comprising:
a decorative film including a metal layer that includes a first area in which an addition concentration of a predetermined element is relatively high, a second area in which the addition concentration is relatively lower than that of the first area, and minute cracks that are formed using the first area as a reference; and
a casing portion including a to-be-decorated area to which the decorative film is to be bonded.

2. The structure according to claim 1, wherein
the predetermined element is oxygen or nitrogen.

3. The structure according to claim 1, wherein
the metal layer is formed of aluminum or silver.

4. The structure according to claim 1, wherein
the metal layer has a thickness of 50 nm or more and 300 nm or less.

5. The structure according to claim 1, wherein
a pitch of the minute cracks is within a range of 1 μm or more and 500 μm or less.

6. The structure according to claim 1, wherein
a surface reflectance of a visible light area of the metal layer is 70% or more.

7. The structure according to claim 1, wherein
the decorative film includes a protection layer laminated on the metal layer, and a surface reflectance of a visible light area of the protection layer is 65% or more.

8. The structure according to claim 1, wherein
the minute cracks are formed to have a net-like appearance.

9. The structure according to claim 1, wherein
the decorative film includes a base portion that supports the metal layer, a tensile breakage intensity of the base portion being smaller than that of the metal layer.

10. The structure according to claim 9, wherein
the base portion is a base film.

11. The structure according to claim 9, wherein
the base portion is a coating layer formed on a base film.

12. The structure according to claim 1, wherein
the addition concentration becomes lower as a whole for an area of the metal layer closer to a front surface of the metal layer in a thickness direction of the metal layer.

13. The structure according to claim 1, wherein
the addition concentration becomes lower as a whole for an area of the metal layer closer to a surface on an opposite side of a front surface of the metal layer in a thickness direction of the metal layer.

14. An electronic apparatus, comprising:
a decorative film including a metal layer that includes a first area in which an addition concentration of a predetermined element is relatively high, a second area in which the addition concentration is relatively lower than that of the first area, and minute cracks that are formed using the first area as a reference;
a casing portion including a to-be-decorated area to which the decorative film is to be bonded; and
an electronic component accommodated in the casing portion.

15. A decorative film, comprising:
a base film; and
a metal layer that is formed on the base film and includes a first area in which an addition concentration of a predetermined element is relatively high, a second area in which the addition concentration is relatively lower than that of the first area, and minute cracks that are formed using the first area as a reference.

16. A structure production method, comprising:
forming a metal layer to which a predetermined element is added on a base film by vapor deposition;
forming minute cracks on the metal layer by stretching the base film;
forming a decorative film including the metal layer on which the minute cracks are formed;
forming a transfer film by bonding a carrier film onto the decorative film; and
forming a molded component such that the decorative film is transferred from the transfer film by an in-mold molding method, a hot stamp method, or a vacuum molding method.

17. A structure production method, comprising:
forming a metal layer to which a predetermined element is added on a base film by vapor deposition;
forming minute cracks on the metal layer by stretching the base film;
forming a transfer film including the metal layer on which the minute cracks are formed; and
forming a molded component such that the metal layer peeled off from the base film is transferred by an in-mold molding method, a hot stamp method, or a vacuum molding method.

18. A structure production method, comprising:
forming a metal layer to which a predetermined element is added on a base film by vapor deposition;
forming minute cracks on the metal layer by stretching the base film;
forming a decorative film including the metal layer on which the minute cracks are formed; and
forming a molded component integrally with the decorative film by an insert molding method.

19. The structure production method according to claim 16, wherein
the step of forming the metal layer includes performing vapor deposition while supplying gas including the predetermined element.

20. The structure production method according to claim 16, wherein
the step of forming the minute cracks includes biaxially stretching the base film by a stretching rate of 2% or less in each axial direction.

21. The structure production method according to claim 16, wherein
the step of forming the metal layer includes performing vacuum vapor deposition on the base film that is conveyed from a feeder roll toward a take-up roll along a circumferential surface of a rotary drum.
